(19) United States
(12) Patent Application Publication
(10) Pub. No.: US 2025/0294706 A1
(43) Pub. Date: Sep. 18, 2025

(54) IMMERSION COOLING TYPE APPARATUS AND METHOD FOR CONTROLLING FLOW

(71) Applicants: SAMSUNG C & T CORPORAOTION, Seoul (KR); DATABEAN CO., LTD., Suwon-si (KR)

(72) Inventors: Ho Suk Kang, Seoul (KR); Ju Hyung Lee, Suwon-si (KR); Joon Ho Park, Anyang-si (KR); Ki Don Yoon, Seoul (KR); Man Kyu Choi, Incheon (KR); Jun Hee Hong, Suwon-si (KR); Jun Hyeok Yoo, Yongin-si (KR); Soo Yong Kim, Yongin-si (KR)

(73) Assignees: SAMSUNG C & T CORPORATOIN, Seoul (KR); DATABEAN CO., LTD., Suwon-si (KR)

(21) Appl. No.: 18/603,617

(22) Filed: Mar. 13, 2024

(51) Int. Cl. H05K 7/20

(52) U.S. Cl. CPC H05K 7/20281; H05K 7/20236; H05K 7/20272; H05K 7/20772

(57) ABSTRACT

The present invention relates to an immersion cooling type apparatus and method for controlling a flow, the apparatus including a pump connected to a tank, in which a target to be cooled is installed and a coolant is accommodated, and configured to circulate the coolant accommodated in the tank, a first temperature sensor installed in the tank and configured to measure a temperature of the coolant, a second temperature sensor installed at the target to be cooled and configured to measure a temperature of the target to be cooled, and a processor configured to determine whether a change in the temperature of the target to be cooled is normal based on data of the target to be cooled, and in a case where the change is normal, determine whether an operation of the pump is necessary based on the temperature of the target to be cooled and the temperature of the coolant, and control a flow of the coolant using the pump. Accordingly, the target to be cooled can be effectively cooled, and unnecessary operation of the pump can be reduced to reduce waste of energy and improve efficiency.

### CROSS-REFERENCE TO RELATED APPLICATION

This application claims priority to and the benefit of Korean Patent Application No. 10-2023-0011622, filed on Jan. 30, 2023, the disclosure of which is incorporated herein by reference in its entirety.

### BACKGROUND

### 1. Field of the Invention

The present invention relates to an immersion cooling type apparatus and method for controlling a flow, and more particularly, to an immersion cooling type apparatus and method for controlling a flow that can control a flow of a coolant based on a temperature of the coolant and a temperature of a central processing unit (CPU) of a device to be cooled.

### 2. Discussion of Related Art

Generally, an electronic device is equipped with a cooling device for cooling a heating element. For example, a server that processes a large amount of data and is operated 24 hours may use a liquid immersion cooling method for continuous cooling.

The liquid immersion cooling method is a method in which a device or heating component to be cooled is placed in a tank accommodating a coolant, and the coolant is circulated to cool the device or component. A plurality of devices or components may be accommodated in the tank.

The liquid immersion cooling method uses a dielectric coolant with high insulation performance to cool the device or component accommodated in the tank. The coolant whose temperature has increased is recovered from the tank by a pump, heat-exchanged through a heat exchanger, and then added to the tank again.

The liquid immersion cooling method controls an operation of the pump based on the temperature of the coolant to control the temperature of the coolant.

However, since it is not possible to check the temperature of the device or component accommodated in the tank just from the temperature of the coolant, there are problems that cooling efficiency is reduced, and power consumption is high.

The related art is disclosed in Korean Unexamined Patent Application Publication No. 10-2020-0071737 (“Electronic system and device cooled by immersion in liquid”).

### SUMMARY OF THE INVENTION

The present invention is directed to an immersion cooling type apparatus and method for controlling a flow that can control a flow of a coolant based on a temperature of the coolant and a temperature of a target to be cooled and improve cooling efficiency.

According to an aspect of the present invention, there is provided an immersion cooling type apparatus for controlling a flow, the apparatus including: a pump connected to a tank, in which a coolant and a target to be cooled are accommodated, and configured to circulate the coolant; a first temperature sensor configured to measure a temperature of the coolant; a second temperature sensor configured to measure a temperature of the target to be cooled; and a processor configured to determine whether a change in the temperature of the target to be cooled that is measured through the second temperature sensor is normal based on data of the target to be cooled, and in a case where the change is normal, control an operation of the pump based on the temperature of the target to be cooled and the temperature of the coolant.

The processor may determine whether the change in the temperature is normal in a case where the temperature of the target to be cooled is a reference temperature or higher and may output a warning in a case where the change in the temperature is determined as abnormal as a result of determining whether the change in the temperature is normal.

Based on a temperature of a heat generating component disposed at the target to be cooled, the processor may determine that a change in the temperature of the heat generating component is normal in at least any one of a case where a use amount of the heat generating component is a predetermined value or more and a case where the use amount of the heat generating component increases.

The processor may determine that the change in the temperature of the heat generating component is abnormal in at least any one of a case where the use amount of the heat generating component is less than the predetermined value and a case where the use amount of the heat generating component has decreased for a predetermined amount of time or more.

The processor may analyze temperature changes relating to the temperature of the target to be cooled and the temperature of the coolant and then may control the pump to operate in a case where a degree of a temperature increase is a predetermined value or more and additional cooling is necessary and may control the pump to not operate in at least any one of a case where the degree of the temperature increase is less than the predetermined value and a case where a temperature change is temporary.

In a case where the target to be cooled is provided as a plurality of targets to be cooled, the processor may control the pump to not operate in a case where temperatures of some of the plurality of targets to be cooled increase and a change in the temperature of the coolant is less than a predetermined variation value.

The processor may create a table relating to a speed of the pump corresponding to the temperature of the target to be cooled, may control the speed of the pump based on the table to control a flow of the coolant, and may control the pump to stop operating once the temperature of the coolant reaches a set temperature.

The apparatus may further include a communication device, and the communication device may receive data relating to a temperature, power, and a water level through a plurality of sensors installed in the tank, receive, from the target to be cooled, data relating to a use amount of a central processing unit (CPU), a use amount of a memory, and a temperature, and apply the received data to the processor.

According to another aspect of the present invention, there is provided an immersion cooling type method for controlling a flow, the method including: an operation in which a first temperature sensor installed in a tank measures a temperature of a coolant accommodated in the tank; an operation in which a second temperature sensor measures a temperature of a target to be cooled disposed inside the tank; an operation in which a processor determines whether a change in the temperature of the target to be cooled is normal based on data received from the target to be cooled; and an operation in which, in a case where the change in the temperature of the target to be cooled is normal, the processor controls an operation of a pump based on the temperature of the target to be cooled and the temperature of the coolant.

In the operation in which the processor determines whether the change in the temperature of the target to be cooled is normal, the processor may determine whether the change in the temperature of the target to be cooled is normal in a case where the temperature of the target to be cooled is a reference temperature or higher.

The operation in which the processor determines whether the change in the temperature of the target to be cooled is normal may include: an operation in which, based on a temperature of a heat generating component disposed at the target to be cooled, the processor determines that a change in the temperature of the heat generating component is normal in at least any one of a case where a use amount of the heat generating component is a predetermined value or more and a case where the use amount of the heat generating component increases; and an operation in which the processor determines that the change in the temperature of the heat generating component is abnormal in at least any one of a case where the use amount of the heat generating component is less than the predetermined value and a case where the use amount of the heat generating component has decreased for a predetermined amount of time or more.

The operation in which the processor controls the operation of the pump may include: an operation in which the processor analyzes temperature changes relating to the temperature of the target to be cooled and the temperature of the coolant; an operation in which the processor controls the pump to operate in a case where a degree of a temperature increase is a predetermined value or more and additional cooling is necessary; and an operation in which the processor controls the pump to not operate in at least any one of a case where the degree of the temperature increase is less than the predetermined value and a case where a temperature change is temporary.

The operation in which the processor controls the operation of the pump may include an operation in which, in a case where the target to be cooled is provided as a plurality of targets to be cooled, the processor controls the pump to not operate in a case where temperatures of some of the plurality of targets to be cooled increase and a change in the temperature of the coolant is less than a predetermined variation value.

The operation in which the processor controls the operation of the pump may include: an operation in which the processor creates a table relating to a speed of the pump corresponding to the temperature of the target to be cooled; an operation in which the processor controls the speed of the pump based on the table to control a flow of the coolant; and an operation in which the processor controls the pump to stop operating once the temperature of the coolant reaches a set temperature.

The method may further include: an operation in which a communication device receives data of the target to be cooled installed inside the tank from the target to be cooled; and an operation in which the communication device receives data relating to the coolant accommodated in the tank, wherein the communication device receives data relating to a temperature, power, and a water level through a plurality of sensors installed in the tank and receives, from the target to be cooled, data relating to a use amount of a central processing unit (CPU), a use amount of a memory, and a temperature.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a view illustrating a configuration of a cooling system including an immersion cooling type apparatus for controlling a flow according to one embodiment of the present invention;

FIG. 2 is a block diagram briefly illustrating a control configuration of the immersion cooling type apparatus for controlling a flow according to one embodiment of the present invention;

FIGS. 3A and 3B are views illustrating changes in a temperature and a flow rate in the immersion cooling type apparatus for controlling a flow according to one embodiment of the present invention; and

FIG. 4 is a flowchart illustrating a flow control method of the immersion cooling type apparatus for controlling a flow according to one embodiment of the present invention.

### DETAILED DESCRIPTION OF EXEMPLARY EMBODIMENTS

Hereinafter, the present invention will be described with reference to the accompanying drawings.

In this process, thicknesses of lines or sizes of components illustrated in the drawings may be exaggerated for clarity and convenience of description. Also, terms used below are terms defined in consideration of functions in the present invention and may be changed according to an intention or customary practice of a user or an operator. Therefore, the terms should be defined based on the content throughout the present specification.

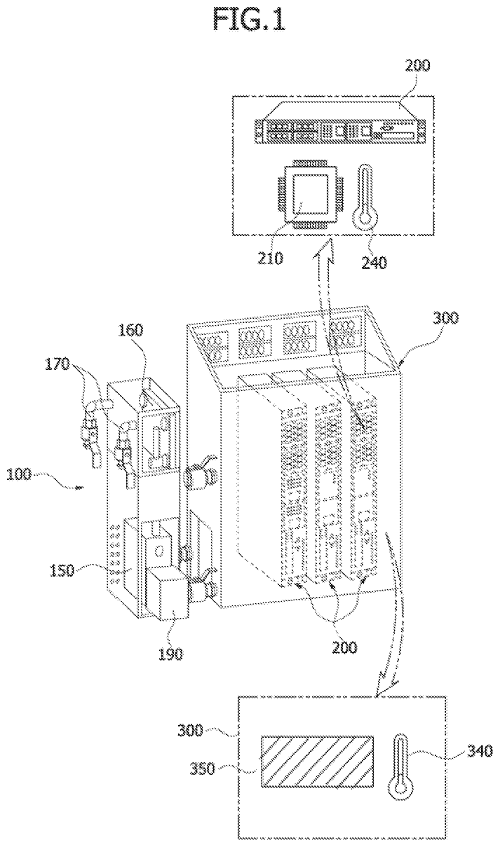

FIG. 1 is a view illustrating a configuration of a cooling system including an immersion cooling type apparatus for controlling a flow according to one embodiment of the present invention.

Referring to FIG. 1, an immersion cooling type flow control apparatus 100 (hereinafter, a control apparatus 100) according to the present invention is connected to a tank 300 and controls a flow of a coolant 350 accommodated in the tank 300 to cool a target to be cooled 200.

The control apparatus 100 includes a pump 190, a cooling distribution unit (CDU) 150, a heat exchanger 160, and a valve 170.

The tank 300 accommodates a dielectric coolant 350 with high insulation performance, and at least one target to be cooled is disposed in the tank 300. For example, the target to be cooled 200 may be an electronic device, a server, or a heat generating component. Hereinafter, description will be given with an example in which the target to be cooled 200 is a server.

Also, at least one first temperature sensor 340 configured to measure a temperature of the accommodated coolant 350 is installed inside the tank 300. A water level sensor configured to measure a water level of the coolant 350 may be further installed in the tank 300, and voltage and current may be measured to calculate an amount of consumed power.

At least one second temperature sensor 240 configured to measure a temperature of a central processing unit (CPU) 210, which is a heat generating component, is installed on the target to be cooled 200. The second temperature sensor 240 may be installed on each target to be cooled 200. Here, although an example in which the heat generating component is a CPU is described, any component other than a CPU may be applied as the heat generating component as long as the component is disposed on a target to be cooled.

The target to be cooled 200 may be mounted in a vertical direction in the tank 300.

The control apparatus 100 receives temperature values measured by the first temperature sensor 340 installed in the tank 300 and the second temperature sensor 240 installed on the target to be cooled 200 and controls the circulation and flow of the coolant. Also, the control apparatus 100 controls an amount of coolant in the tank 300.

The pump 190 recovers the coolant 350 from the tank 300, supplies the coolant 350 to the heat exchanger 160, and controls the circulation of the coolant so that the coolant 350 heat-exchanged in the heat exchanger 160 is supplied to the tank 300 again.

The heat exchanger 160 exchanges heat of the coolant 350 circulated by the pump 190 using a separate cooler or fan and discharges the cooled coolant. Here, cooling water or a coolant may be used as the cooler, and the heat exchanger 160 may cool the coolant 350 in a liquid-to-liquid heat exchange manner using the cooler. Also, the heat exchanger 160 may exchange heat of the coolant 350 using cooled air supplied through the fan.

The CDU 150 supplies the cooler to the heat exchanger 160 and controls the amount of the cooler to allow liquid-to-liquid heat exchange to occur in the heat exchanger 160, thereby controlling a cooling temperature of the coolant 350.

The valve 170 is provided as a plurality of valves 170, and the valves 170 open so that the coolant 350 is supplied to the tank or block the supply of the coolant 350. Also, the valves 170 may supply the cooler to the heat exchanger 160 or block the supply of the cooler. The valves may be connected to a separate cooler supply device (not illustrated).

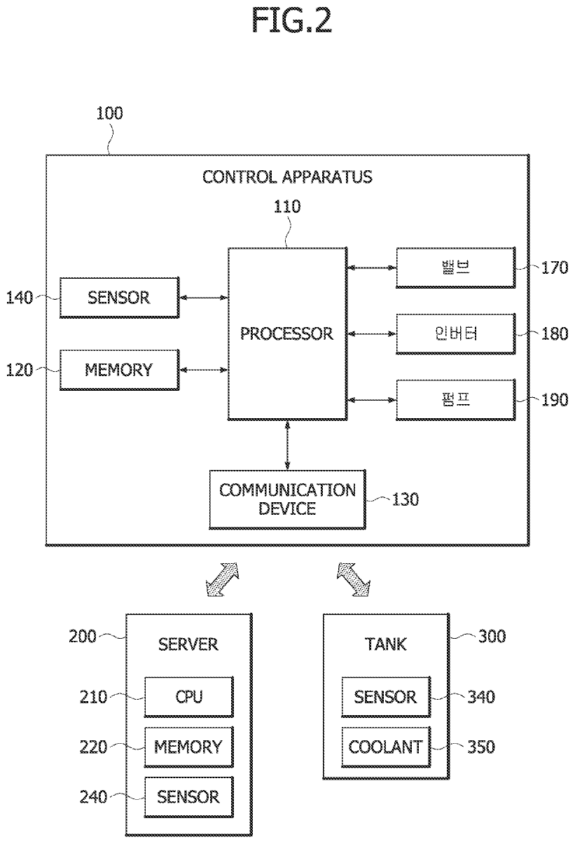

FIG. 2 is a block diagram briefly illustrating a control configuration of the immersion cooling type apparatus for controlling a flow according to one embodiment of the present invention.

Referring to FIG. 2, the control apparatus 100 includes the pump 190, an inverter 180, the valves 170, a communication device 130, a memory 120, a sensor 140, and a processor 110.

Also, as described above, the control apparatus 100 controls the CDU 150 to control the flow of the coolant and the cooler in the heat exchanger 160.

The control apparatus 100 may be connected to the tank 300 to receive data of the tank and receive data of a server which is the target to be cooled 200.

The sensor 140 may be provided as a plurality of sensors 140, and the sensors 140 may measure at least one of temperature, pressure, water level, current, and voltage.

The sensors 140 include the first temperature sensor 340 installed in the tank 300 and the second temperature sensor 240 installed on the server which is the target to be cooled 200. Also, the sensors 140 may include temperature sensors installed at an inlet of a coolant and an outlet thereof connected to the tank 300.

The first temperature sensor 340 measures a temperature of the coolant 350 accommodated in the tank 300 and applies the measured temperature to the processor 110. Also, a water level sensor may be installed in the tank 300.

The second temperature sensor 240 measures a temperature of the CPU 210 of the server which is the target to be cooled 200 and applies the measured temperature to the processor 110. According to circumstances, the processor 110 may receive and use a value measured by a temperature sensor provided on the server itself which is the target to be cooled 200.

The memory 120 stores data measured by a plurality of sensors (not illustrated) and data transmitted and received through the communication device 130. The memory 120 stores data relating to a temperature and a flow rate and stores data for the processor 110 to control the pump 190.

The memory 120 may store data relating to at least one of a temperature control algorithm, a flow control algorithm, and a cooling system operation algorithm.

The memory 120 may include a storage device such as a random-access memory (RAM), a nonvolatile memory including a read-only memory (ROM) and an electrically erasable programmable ROM (EEPROM), or a flash memory.

The communication device 130 receives data relating to the tank 300, is connected to the server which is the target to be cooled 200, receives data therefrom, stores the data in the memory 120, and applies the received data to the processor 110.

The communication device 130 may receive data relating to a value (coolant temperature) measured by the first temperature sensor 340 of the tank 300, the water level of the coolant, and power consumption.

The communication device 130 receives a value (CPU temperature) measured by the second temperature sensor 240 of the server which is the target to be cooled 200 and receives data of the CPU 210 and a memory 220 of the server.

The communication device 130 may include a wired or wireless communication module. For example, the communication device 130 may include at least one of mobile communication, serial communication, and short-range communication such as Ethernet, Wi-Fi, and Bluetooth.

The inverter 180 operates according to a control signal of the processor 110 and controls driving of the pump 190. The pump 190 operates by operation power supplied from the inverter 180 and circulates the coolant 350 accommodated in the tank 300. A separate driver may be provided according to a driving method of the pump 190.

The valve 170 is provided as the plurality of valves 170, and the valves 170 are opened or closed according to control of the processor 110. The valves 170 supply cooling water to the heat exchanger 160 or block supply of the cooling water. Also, the valves 170 may additionally supply the coolant 350 or block the supply of the coolant 350.

The processor 110 controls the flow or flow rate of the coolant 350 corresponding to the values measured by the sensors 140, the first temperature sensor 340, and the second temperature sensor 240. The processor 110 may control driving of the pump 190 through the inverter 180 to control the flow or flow rate of the coolant 350.

The processor 110 receives data of the server, which is the target to be cooled 200, through the communication device 130 and determines whether a temperature change is normal based on a use amount of the CPU 210 and the memory 220. The processor 110 may determine whether a temperature change is normal to detect whether there is an error in the cooling system itself.

The processor 110 may compare a temperature change of the temperature of the CPU 210 measured through the second temperature sensor 240 and a temperature change of the temperature of the coolant 350 measured through the first temperature sensor 340 and determine whether the temperature change is normal.

Also, when the temperature change is normal, the processor 110 determines whether driving of the pump 190 is necessary based on the temperature change. The processor 110 controls driving of the pump 190 through the inverter 180 to supply the cooled coolant to the tank 300 and controls the pump 190 to stop operating once the temperature of the coolant reaches a predetermined temperature.

When the temperature of the coolant 350 or the temperature of the CPU 210 increases, the processor 110 may determine whether the temperature increase is due to an increase in the use amount of the CPU 210 and the memory 220 and determine whether the temperature change is normal.

For example, when the use amount of the CPU 210 and the memory 220 increases, and the temperature of the CPU 210 measured by the second temperature sensor 240 and the temperature of the coolant measured by the first temperature sensor 340 increase, the processor 110 may determine that the temperature change is normal and may control the operation of the pump 190 to supply the cooled coolant.

Also, when a plurality of targets to be cooled 200 are present, the processor 110 may determine whether the temperature change is normal based on data of each target to be cooled 200 and the temperature of each CPU.

For example, in a state in which a temperature of a CPU of a first server among the targets to be cooled 200 is a reference temperature or higher, and temperatures of CPUs of a second server and a third server are under the reference temperature, when a temperature increase of a coolant is a predetermined value or more, the processor 110 may determine that the temperature increase is abnormal.

The processor 110 may determine that there is an abnormality in a temperature sensor or an abnormality in a CPU.

Also, when the temperature increase of the coolant is normal, since a temperature change is small, the processor 110 may control the pump 190 to not operate.

The processor 110 may compare a temperature change of the temperature of the CPU 210 measured through the second temperature sensor 240 and a temperature change of the temperature of the coolant 350 measured through the first temperature sensor 340 and determine whether the temperature change is normal.

For example, when a value measured by the second temperature sensor 240 increases in a state in which the use amount of the CPU 210 is less than a predetermined value, or when the temperature of the coolant measured by the first temperature sensor 340 increases in a state in which the value measured by the second temperature sensor 240 is low, the processor 110 may determine that the temperature change is abnormal.

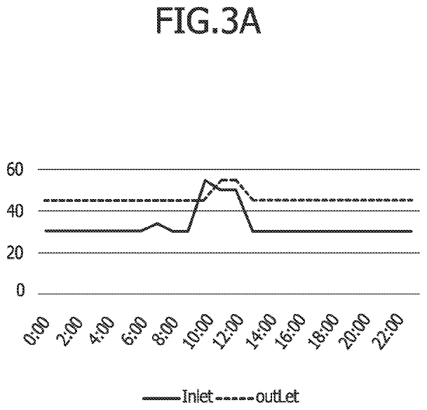

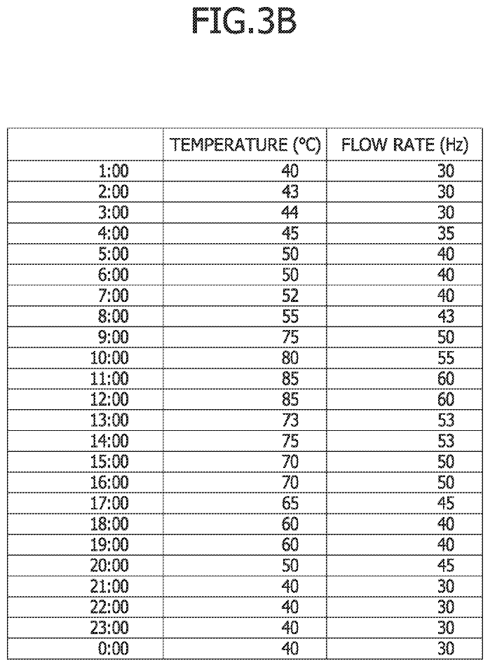

FIGS. 3A and 3B views illustrating changes in a temperature and a flow rate in the immersion cooling type apparatus for controlling a flow according to one embodiment of the present invention.

Referring to FIG. 3A, a temperature change of a coolant may be checked through the temperature sensors installed at the inlet of the coolant and the outlet thereof connected to the tank 300.

The coolant 350 is cooled and injected into the tank 300, and according to a degree of a temperature increase of the target to be cooled 200 installed inside the tank 300, the coolant 350 absorbs heat, and the temperature of the coolant 350 increases. In the state in which the temperature thereof has increased, the coolant 350 is discharged through the outlet by the pump. The discharged coolant is re-cooled through the heat exchanger 160 and supplied to the tank 300 through the inlet.

When the temperature of the target to be cooled 200 increases, the target to be cooled 200 is cooled by the coolant 350, and the temperature of the target to be cooled 200 decreases again.

Referring to FIG. 3B, the processor 110 creates a table relating to a speed of the pump corresponding to the temperature of the target to be cooled 200, that is, the CPU, stores the table in the memory, and controls the speed of the pump according to the temperature of the CPU to control the flow.

When the target to be cooled 200 generates heat, for example, when the temperature of the CPU 210 increases, the processor 110 controls the flow of the coolant 350 based on the temperature of the CPU 210 and the temperature of the coolant.

When a degree of the temperature increase is large, the processor 110 controls the pump 190 so that the flow rate or flow of the coolant 350 increases.

The processor 110 increases the flow rate of the coolant with an increase in the temperature of the CPU 210 of the target to be cooled 200 and decreases the flow rate of the coolant with a decrease in the temperature of the CPU 210.

For example, in a case in which the temperature of the CPU 210 increases, when the temperature is lower than 45° C., the processor 110 controls the pump 190 by setting the speed of the pump 190 to 30 Hz. Also, the processor 110 controls the flow rate by setting the speed of the pump 190 to 35 Hz when the temperature is higher than or equal to 45° C. and lower than 50° C., 40 Hz when the temperature is higher than or equal to 50° C. and lower than 55° C., 43 Hz when the temperature is higher than or equal to 55° C. and lower than 60° C., 50 Hz when the temperature is higher than or equal to 75° C. and lower than 80° C., 55 Hz when the temperature is higher than or equal to 80° C. and lower than 85° C., and 60 Hz when the temperature is higher than or equal to 85° C.

Meanwhile, in a case in which the temperature of the CPU 210 decreases, the processor 110 may control the flow rate of the coolant 350 differently from the case in which the temperature of the CPU 210 increases. For example, the processor 110 controls the flow rate by setting the speed of the pump 190 to 53 Hz when the temperature is 75° C., 50 Hz when the temperature is 70° C., 40 Hz when the temperature is 60° C., 45 Hz when the temperature is 50° C., and 30 Hz when the temperature is 40° C.

The flow and flow rate of the coolant 350 increase with an increase in the speed of the pump 190, and the flow and flow rate of the coolant 350 decrease with a decrease in the speed of the pump 190.

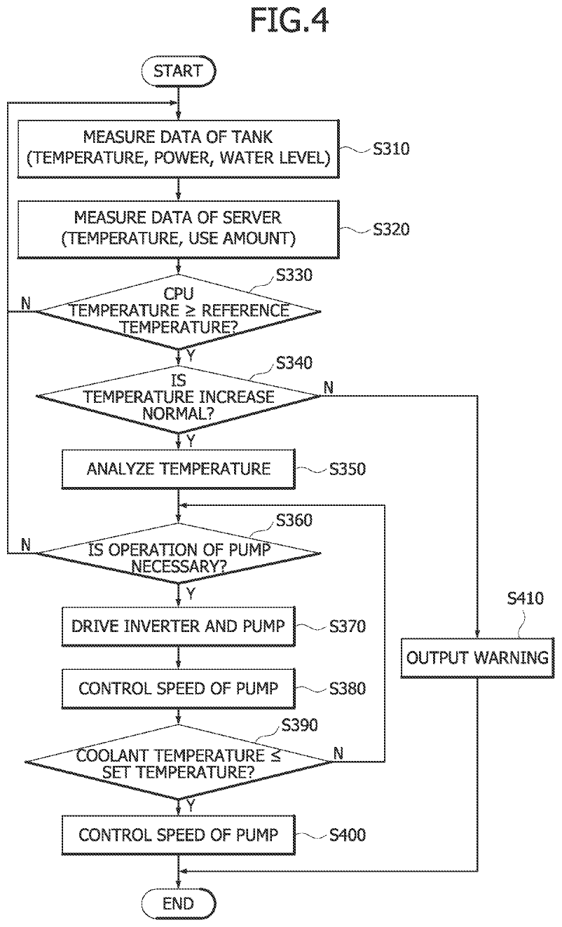

FIG. 4 is a flowchart illustrating a flow control method of the immersion cooling type apparatus for controlling a flow according to one embodiment of the present invention.

Referring to FIG. 4, a sensor installed in the tank 300 measures data relating to the tank (S310).

In the tank 300 in which the target to be cooled 200 is installed, the first temperature sensor 340 measures the temperature of the coolant 350, and the water level sensor measures the water level of the coolant 350. Also, the power consumption may be measured in the tank 300.

The server 200 measures the temperature of the CPU 210 through the second temperature sensor 240 and measures the use amount of the CPU 210 and the memory 220 (S320).

The processor 110 receives data measured through the sensor installed in the tank 300 and receives data measured by the server which is the target to be cooled 200.

The processor 110 determines whether the temperature of the CPU 210 measured through the second temperature sensor 240 is a reference temperature or higher (S330).

When the temperature of the CPU 210 is lower than the reference temperature, the processor 110 waits and receives the measurement data of the tank 300 and the target to be cooled 200.

When the temperature of the CPU 210 is the reference temperature or higher, the processor 110 determines whether the temperature increase is normal (S340).

The processor 110 may determine whether the temperature increase is normal corresponding to the use amount of the CPU 210 and an increase in the use amount. The processor 110 determines that the temperature increase is normal when the use amount of the CPU 210 is a predetermined value or more or the use amount has increased.

Meanwhile, the processor 110 may determine that the temperature increase is abnormal when the temperature increases in a state in which the use amount of the CPU 210 is less than the predetermined value or the use amount has decreased for a predetermined amount of time or more.

When the temperature increase is determined as abnormal, the processor 110 generates and outputs a warning (S410). The processor 110 may output a warning through at least one of a warning sound, a warning message, and voice guidance.

When the temperature increase of the CPU 210 is determined as normal, the processor 110 analyzes the temperature of the coolant 350 and the temperature of the CPU 210 (S350).

The processor 110 compares a change in the temperature of the CPU and a change in the temperature of the coolant and determines a degree of the temperature change. Also, the processor 110 analyzes a change in the temperature of each CPU for the plurality of targets to be cooled 200.

The processor 110 determines whether the operation of the pump is necessary based on analysis results (S360).

The processor 110 determines that the operation of the pump is necessary when the degree of the temperature increase is a predetermined value or more and additional cooling is necessary and determines that the operation of the pump is unnecessary when the degree of the temperature increase is less than the predetermined value or the temperature change is temporary.

For example, the processor 110 may determine that the operation of the pump is unnecessary when a temperature increase of the CPU is temporary, when a temperature increase of the CPU has occurred in only some of the plurality of targets to be cooled, or when a temperature change of the coolant is less than a predetermined variation value despite a temperature increase of the CPU.

Meanwhile, the processor 110 may determine that the operation of the pump is necessary when the temperature increase of the CPU occurs in all of the plurality of targets to be cooled or when a degree of the temperature increase per second of the CPU is a set value or more.

When the operation of the pump is determined as necessary, the processor 110 controls driving of the pump 190 through the inverter 180 (S370).

The processor 110 sets the speed of the pump based on a temperature change and controls the flow and flow rate of the coolant 350 (S380).

Also, the processor 110 controls the CDU 150 so that the heat exchanger 160 exchanges heat of the coolant introduced thereinto.

Here, the processor 110 may control a valve or a nozzle to set an amount of supplied coolant to be different for each target to be cooled 200. The processor 110 may control the coolant 350 to be supplied to any one target to be cooled 200 in which a temperature change of the CPU is large.

By driving of the pump 190, the coolant is recovered from the tank 300, moved to the heat exchanger 160, cooled in the heat exchanger, and then supplied to the tank 300 again.

By decreasing the temperature of the coolant of the tank 300 through the supply of the cooled coolant, the processor 110 may prevent the temperature of the target to be cooled 200 from decreasing or increasing to a predetermined temperature or more.

The processor 110 determines whether the temperature of the coolant measured through the first temperature sensor 340 is a set temperature or lower (S390).

When the temperature of the coolant is the set temperature or lower, the processor 110 controls the speed of the pump so that the flow of the coolant decreases (S400). The processor 110 controls the speed of the pump 190 to reduce the flow of the coolant or stops the operation of the pump.

Therefore, using an immersion cooling type apparatus and method for controlling a flow according to one aspect of the present invention, a target to be cooled may be effectively cooled by controlling a flow of a coolant based on a temperature of a CPU of the target to be cooled as well as a temperature of the coolant, and waste of energy may be reduced and efficiency may be improved by reducing unnecessary operation of a pump. Also, using the immersion cooling type apparatus and method for controlling a flow according to the present invention, an abnormal operation may be easily detected by checking, based on data of the target to be cooled, whether a temperature change of the CPU is normal or is due to an error.

According to one aspect, an immersion cooling type apparatus and method for controlling a flow according to the present invention can determine whether an operation of a pump is necessary and control a flow of a coolant based on a temperature of the coolant and a temperature of a target to be cooled, thereby effectively cooling the target to be cooled and reducing unnecessary operation of the pump to reduce waste of energy and improve efficiency.

According to one aspect of the present invention, whether a measured temperature change is normal can be determined based on data of a target to be cooled, and abnormal operation due to an error can be easily detected.

The present invention has been described above with reference to the embodiments illustrated in the drawings, but the description is merely illustrative, and those of ordinary skill in the art should understand that various modifications and other equivalent embodiments are possible therefrom. Therefore, the true technical protection scope of the present invention should be defined by the claims below.

What is claimed is:

1. An immersion cooling type apparatus for controlling a flow, the apparatus comprising:
a pump connected to a tank, in which a coolant and a target to be cooled are accommodated, and configured to circulate the coolant;
a first temperature sensor configured to measure a temperature of the coolant;
a second temperature sensor configured to measure a temperature of the target to be cooled; and
a processor configured to determine whether a change in the temperature of the target to be cooled that is measured through the second temperature sensor is normal based on data of the target to be cooled, and in a case where the change is normal, control an operation of the pump based on the temperature of the target to be cooled and the temperature of the coolant.

2. The apparatus of claim 1, wherein the processor determines whether the change in the temperature is normal in a case where the temperature of the target to be cooled is a reference temperature or higher and outputs a warning in a case where the change in the temperature is determined as abnormal as a result of determining whether the change in the temperature is normal.

3. The apparatus of claim 2, wherein, based on a temperature of a heat generating component disposed at the target to be cooled, the processor determines that a change in the temperature of the heat generating component is normal in at least any one of a case where a use amount of the heat generating component is a predetermined value or more and a case where the use amount of the heat generating component increases.

4. The apparatus of claim 3, wherein the processor determines that the change in the temperature of the heat generating component is abnormal in at least any one of a case where the use amount of the heat generating component is less than the predetermined value and a case where the use amount of the heat generating component has decreased for a predetermined amount of time or more.

5. The apparatus of claim 1, wherein the processor analyzes temperature changes relating to the temperature of the target to be cooled and the temperature of the coolant and controls the pump to operate in a case where a degree of a temperature increase is a predetermined value or more and additional cooling is necessary and controls the pump to not operate in at least any one of a case where the degree of the temperature increase is less than the predetermined value and a case where a temperature change is temporary.

6. The apparatus of claim 1, wherein, in a case where the target to be cooled is provided as a plurality of targets to be cooled, the processor controls the pump to not operate in a case where temperatures of some of the plurality of targets to be cooled increase and a change in the temperature of the coolant is less than a predetermined variation value.

7. The apparatus of claim 1, wherein the processor creates a table relating to a speed of the pump corresponding to the temperature of the target to be cooled, controls the speed of the pump based on the table to control a flow of the coolant, and controls the pump to stop operating once the temperature of the coolant reaches a set temperature.

8. The apparatus of claim 1, further comprising a communication device,
wherein the communication device receives data relating to a temperature, power, and a water level through a plurality of sensors installed in the tank, receives, from the target to be cooled, data relating to a use amount of a central processing unit (CPU), a use amount of a memory, and a temperature, and applies the received data to the processor.

9. An immersion cooling type method for controlling a flow, the method comprising:
an operation in which a first temperature sensor installed in a tank measures a temperature of a coolant accommodated in the tank;
an operation in which a second temperature sensor measures a temperature of a target to be cooled disposed inside the tank;
an operation in which a processor determines whether a change in the temperature of the target to be cooled is normal based on data received from the target to be cooled; and
an operation in which, in a case where the change in the temperature of the target to be cooled is normal, the processor controls an operation of a pump based on the temperature of the target to be cooled and the temperature of the coolant.

10. The method of claim 9, wherein, in the operation in which the processor determines whether the change in the temperature of the target to be cooled is normal, the processor determines whether the change in the temperature of the target to be cooled is normal in a case where the temperature of the target to be cooled is a reference temperature or higher.

11. The method of claim 10, wherein the operation in which the processor determines whether the change in the temperature of the target to be cooled is normal includes:
an operation in which, based on a temperature of a heat generating component disposed at the target to be cooled, the processor determines that a change in the temperature of the heat generating component is normal in at least any one of a case where a use amount of the heat generating component is a predetermined value or more and a case where the use amount of the heat generating component increases; and
an operation in which the processor determines that the change in the temperature of the heat generating component is abnormal in at least any one of a case where the use amount of the heat generating component is less than the predetermined value and a case where the use amount of the heat generating component has decreased for a predetermined amount of time or more.

12. The method of claim 9, wherein the operation in which the processor controls the operation of the pump includes:
an operation in which the processor analyzes temperature changes relating to the temperature of the target to be cooled and the temperature of the coolant;
an operation in which the processor controls the pump to operate in a case where a degree of a temperature increase is a predetermined value or more and additional cooling is necessary; and
an operation in which the processor controls the pump to not operate in at least any one of a case where the degree of the temperature increase is less than the predetermined value and a case where a temperature change is temporary.

13. The method of claim 9, wherein the operation in which the processor controls the operation of the pump includes an operation in which, in a case where the target to be cooled is provided as a plurality of targets to be cooled, the processor controls the pump to not operate in a case where temperatures of some of the plurality of targets to be cooled increase and a change in the temperature of the coolant is less than a predetermined variation value.

14. The method of claim 9, wherein the operation in which the processor controls the operation of the pump includes:
an operation in which the processor creates a table relating to a speed of the pump corresponding to the temperature of the target to be cooled;
an operation in which the processor controls the speed of the pump based on the table to control a flow of the coolant; and
an operation in which the processor controls the pump to stop operating once the temperature of the coolant reaches a set temperature.

15. The method of claim 9, further comprising:
an operation in which a communication device receives data of the target to be cooled installed inside the tank from the target to be cooled; and
an operation in which the communication device receives data relating to the coolant accommodated in the tank,
wherein the communication device receives data relating to a temperature, power, and a water level through a plurality of sensors installed in the tank and receives, from the target to be cooled, data relating to a use amount of a central processing unit (CPU), a use amount of a memory, and a temperature.
